(19) United States
(12) Patent Application Publication
(10) Pub. No.: US 2025/0386612 A1
(43) Pub. Date: Dec. 18, 2025

(54) PHOTO-SENSING DEVICE AND MANUFACTURING METHOD THEREOF

(71) Applicant: Taiwan Semiconductor Manufacturing Company, Ltd., Hsinchu (TW)

(72) Inventors: Yu-Yuan PENG, Hsinchu (TW); Yu-Ciao CHEN, Hsinchu (TW); Han-Yu WANG, Hsinchu (TW); Yen-Yu CHEN, Hsinchu (TW); Yen-Ting CHIANG, Hsinchu (TW); Tzu-Jui WANG, Hsinchu (TW); Jen-Cheng LIU, Hsinchu (TW)

(73) Assignee: Taiwan Semiconductor Manufacturing Company, Ltd., Hsinchu (TW)

(21) Appl. No.: 18/740,790

(22) Filed: Jun. 12, 2024

(51) Int. Cl. H01L 27/146

(52) U.S. Cl. CPC H10F 39/807; H10F 39/028

(57) ABSTRACT

A photo-sensing device includes a substrate and a trench isolation. The substrate has a pixel region. The trench isolation is disposed within the substrate, defines the pixel region and incudes an etching stop layer and an isolation structure. The isolation layer is connected with the etching stop layer. The etching stop layer has a minimum width in a direction, the isolation portion has a maximum width in the direction, and the minimum width and the maximum width are different.

### BACKGROUND

Related DTI (Deep trench isolation) is usually constructed in back-side process, more thermal budget concern leads to less annealing to repair Si damage from trench dry etch process. In addition, a large DTI structure as back-side DTI stop layer, it may cause less Si active area and less high-k electric passivation area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a local cross-sectional view of a photo-sensing device according to an embodiment of the present disclosure; and

FIGS. 2A to 2Z2 illustrate schematic diagrams of manufacturing processes of the photo-sensing device of FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

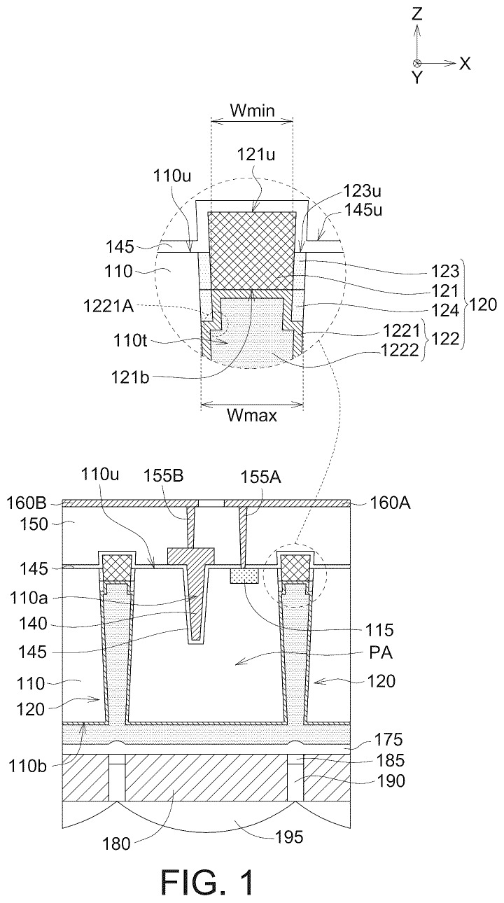

As illustrated in FIG. 1, FIG. 1 illustrates a schematic diagram of a local cross-sectional view of a photo-sensing device 100 according to an embodiment of the present disclosure. The photo-sensing device 100 may be a complementary metal-oxide semiconductor image sensor (CIS). The photo-sensing device 100 has an array of pixel sensors. A pixel sensor records incident radiation (e.g., visible light) using a photodetector, and facilitates digital readout of the recording with a plurality of pixel devices (e.g., a transfer transistor, a reset transistor, etc.) disposed on a front-side of a substrate. The pixel sensors include an array of photodetectors (e.g., a 2×2, 2×4, or 4×4 photodetector pixel sensor).

As illustrated in FIG. 1, the photo-sensing device 100 includes a substrate 110, at least one doping region 115, at least one trench isolation 120, at least one gate 140, at least one gate oxide layer 145, a dielectric layer 150, at least one contact via (for example, contact vias 155A and 155B), a conductive trace (for example, conductive traces 160A and 160B), a layer 175, a plurality of light filters 180, a plurality of conductive grid structure 185, a plurality of dielectric grid structure 190 and a plurality of micro-lenses 148. The substrate 100 has at least one pixel region PA (or photodetector). The trench isolation 120 is disposed within the substrate 110 and defines the pixel region PA. The trench isolation 120 includes an etching stop layer 121 and an isolation structure 122. The isolation structure 122 is connected with the etching stop layer 121.

As illustrated in FIG. 1, in an embodiment, the etching stop layer 121 has a minimum width Wₘᵢₙ in a direction X, the isolation portion 120 has a maximum width W max in the direction X, and the minimum width Wₘᵢₙ may be different from the maximum width Wₘₐₓ. For example, the minimum width Wₘᵢₙ may be less than the maximum width Wₘₐₓ.

The photo-sensing device 100 may be applied to a camera (not illustrated). In addition, the photo-sensing device 100 may be electrically connected with a display (not illustrated), wherein the display may display a frame or a picture according to the sensing signal of the photo-sensing device 100.

As illustrated in FIG. 1, the substrate 110 is, for example, a portion of a silicon (Si) wafer. Viewed from a top of the photo-sensing device 100, the trench isolation 120 may surround the pixel region PA for isolating adjacent two pixel regions PA. Through the photoelectric effect, electrons may be generated in the pixel region PA when the pixel region PA is illuminated by light (the light may illuminate the second surface 110b of the substrate 110). One of the pixel regions PA may sense one type of light color, such as red, green or blue, and different two of the pixel regions PA may sense different types of light color.

As illustrated in FIG. 1, the substrate 110 has at least one trench 110t, a first surface 110u and a second surface 110b opposite to the first surface 110u. In an embodiment, the first surface 110u defines a front-side of the substrate 110, and the second surface 110b defines a back-side of the substrate 110. The trench 110t extends to the second surface 110b from the first surface 110u. In an embodiment, the trench 110t has an inner width in the direction X which decreasing from the first surface 110u to the second surface 110b (for example, in a direction-Z). At least one portion of the trench isolation 120 is disposed within the trench 110t, and the trench isolation 120 may be exposed form the first surface 110u and the second surface 110b. In an embodiment, the trench 110t is, for example, a DTI (Deep trench isolation), or FDTI (Full Deep trench isolation).

As illustrated in FIG. 1, the doping region 115 may be formed within the substrate 110 by using, for example, implanting, etc. The doping region 115 may serve as a drain or a source of an image sensing unit. The structure as illustrated in FIG. 1 may define one image sensing unit, for example. In an embodiment, the doping region 115 may be drain region, for example, N-type doping region.

The etching stop layer 121 may be formed of, for example, poly silicon, silicon nitride, silicon carbide, silicon oxynitride, silicon oxycarbide, or the like.

As illustrated in FIG. 1, the trench isolation 120 further includes a first oxide layer 123 and a second oxide layer 124. The isolation structure 122, the first oxide layer 123 and the second oxide layer 124 are disposed within the trench 110t, and a portion of the etching stop layer 121 may be disposed outside the trench 110t. In the present embodiment, the trench isolation 120 may be one-piece formed full trench isolation with protrusive etching stop layer. In another embodiment, the trench isolation 120 may be one-piece formed full trench isolation without protrusive etching stop layer.

As illustrated in FIG. 1, the etching stop layer 121 may protrude relative to the first surface 110u. The etching stop layer 121 covers the first oxide layer 123. In an embodiment, the etching stop layer 121 has a first surface 121u and a second surface 121b opposite to the first surface 121u.

As illustrated in FIG. 1, the isolation structure 122 is a multi-layered structure. For example, the isolation structure 122 includes a high dielectric constant (high-k) portion 1221 and an oxide portion 1222. The high-k portion 1221 is disposed on a sidewall of the trench 110t and the second surface 121b of the etching stop layer 121. The oxide portion 1222 covers the high-k portion 1221. The high-k portion 1221 covers an end and a lateral surface of the second oxide layer 124 and the second surface 121b of the etching stop layer 121. In addition, the high-k portion 1221 conforms with the shapes of the second oxide layer 124 and the etching stop layer 121 to form a step-structure 1221A.

The high-k portion 1221 may be formed of a material including: (i) a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂), and (ii) a high-k dielectric material having oxides of lithium (Li), beryllium (Be), magnesium (Mg), calcium (Ca), strontium (Sr), scandium (Sc), yttrium (Y), zirconium (Zr), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), (iii) other suitable high-k dielectric materials, or (iv) a combination thereof. As used herein, the term “high-k” refers to a high dielectric constant. In the field of semiconductor device structures and manufacturing processes, high-k refers to a dielectric constant that is greater than the dielectric constant of SiO₂ (e.g., greater than 3.9).

As illustrated in FIG. 1, the first oxide layer 123 is disposed on a sidewall of the trench 110t. The first oxide layer 123 may be aligned with the first surface 110u of the substrate 110, or the first oxide layer 123 may be protruded or recessed relative to the first surface 110u of the substrate 110.

As illustrated in FIG. 1, the second oxide layer 124 is disposed on the sidewall of the trench 110t, connected with the first oxide layer 123 and protrudes relative to the second surface 121b of the etching stop layer 121. In the present embodiment, there is an interface between the first oxide layer 123 and the second oxide layer 124. Depending on process parameter, there is no interface between the first oxide layer 123 and the second oxide layer 124. In addition, the first oxide layer 123 and the second oxide layer 124 may be formed of the same material. In another embodiment, the second oxide layer 124 may be omitted, and/or the first oxide layer 123 may protrude relative to the second surface 121b of the etching stop layer 121.

As illustrated in FIG. 1, the gate 140 is disposed within a hole 110a of the substrate 110. The hole 110a extends toward the second surface 110b of the substrate 110 from the first surface 110u of the substrate 110. In addition, the gate 140 may be formed of a material including, for example, poly silicon, metal, etc.

As illustrated in FIG. 1, the gate dielectric layer 145 is formed on first surface 110u of the substrate 110, a first surface 123u of the first oxide layer 123 and the first surface 121u and a lateral surface of the etching stop layer 121. In the present embodiment, the gate dielectric layer 145 may conform with the shapes of the substrate 110, the first oxide layer 123 and the etching stop layer 121.

As illustrated in FIG. 1, the dielectric layer 150 covers the trench isolation 120, the gate 140 and the gate dielectric layer 145. The contact via 155A may be connected with the doping region 115 through the dielectric layer 150 and the gate oxide layer 145. The contact via 155B may be connected with the gate 140 through the dielectric layer 150. The conductive trace 160A is formed on the dielectric layer 150 and electrically connected with the contact via 155A, and the conductive trace 160B is formed on the dielectric layer 150 and electrically connected with the contact via 155B. A control signal (for example, voltage) may be applied to the gate 140 to turn on a switch, so that a current signal (generated by the electrons in the pixel region PA) may be transmitted to an external device (not illustrated) through the contact via 155A and the conductive trace 160A. In addition, the contact vias 155A and 155B may be formed of metal, and the conductive traces 160A and 160B may be formed of metal.

As illustrated in FIG. 1, the layer 175 is formed over the oxide portion 1222 of the trench isolation 120. The layer 175 may, for example, be or includes an oxide, such as silicon dioxide, or the like. In some embodiments, the layer 175 is formed by a PVD process, a CVD process, an ALD process, or some other suitable growth or deposition process. In another embodiment, the layer 175 may be ARC (Anti-reflective coating). The conductive grid structure 185 is formed over the layer 175 and the dielectric grid structure 190 is formed over the conductive grid structure 185.

The conductive grid structure 185 overlies the layer 175 and the dielectric grid structure 190 overlies the conductive grid structure 185. The conductive grid structure 185 and the dielectric grid structure 190 include sidewalls that define a plurality of openings overlying the pixel regions PA. In various embodiments, the conductive grid structure 185 includes one or more metal layers that is/are configured to reduce cross-talk between adjacent pixel regions PA, thereby increasing optical isolation of the image sensor. In addition, the dielectric grid structure 190 is configured to direct light to the pixel regions PA by total internal reflection such that cross-talk is further reduced and a quantum efficiency of the pixel regions PA is increased.

In some embodiments, a process for forming the conductive grid structure 185 and the dielectric grid structure 190 comprises: depositing (e.g., by PVD, CVD, ALD, electroplating, electroless plating, etc.) a metal grid layer over the layer 175; depositing (e.g., by PVD, CVD, ALD, etc.) a dielectric grid layer on the metal grid layer; forming a masking layer (not shown) over the dielectric grid layer; patterning the metal grid layer and the dielectric grid layer according to the masking layer; and performing a removal process to remove the masking layer.

As illustrated in FIG. 1, the light filters 180 are formed over or corresponding to the pixel regions PA. Each micro-lens 195 is formed over the corresponding light filter 180. A plurality of light filters 180 is disposed in the plurality of openings defined by the sidewalls of the conductive grid structure 185 and the dielectric grid structure 190. The light filters 180 are configured to transmit specific wavelengths of incident light while blocking other wavelengths of incident light. A plurality of micro-lenses 195 overlies the light filters 180 and is configured to focus the incident light towards the pixel regions PA.

In some embodiments, the light filters 180 and the micro-lenses 195 may be deposited by, for example, CVD, PVD, ALD, or some other suitable deposition or growth process.

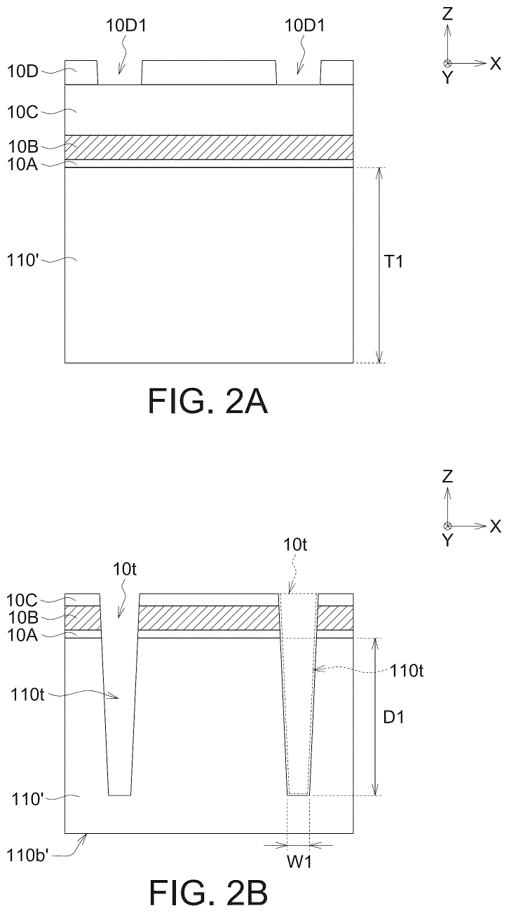

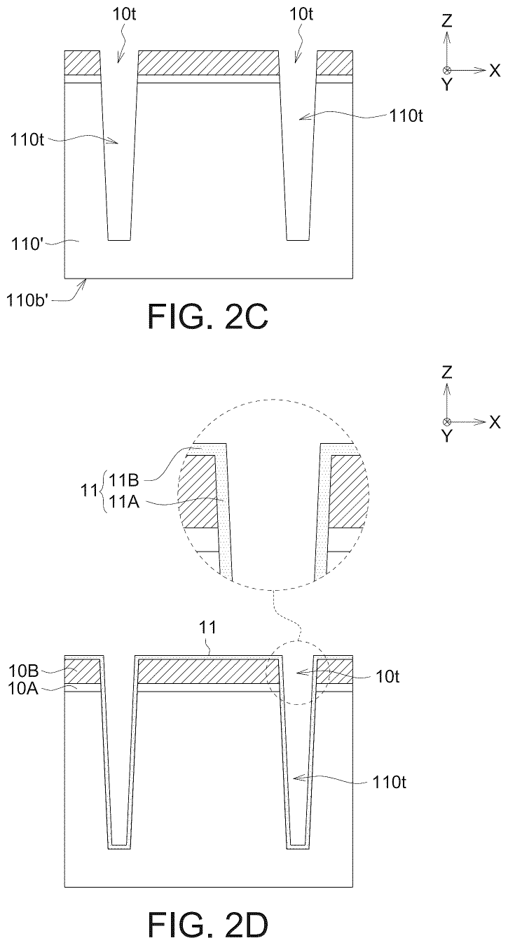

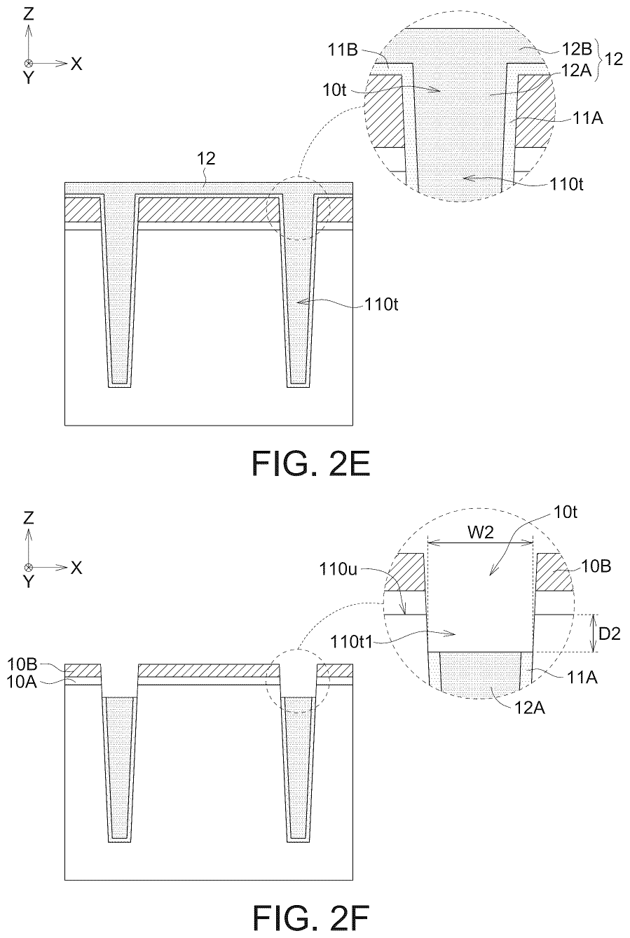

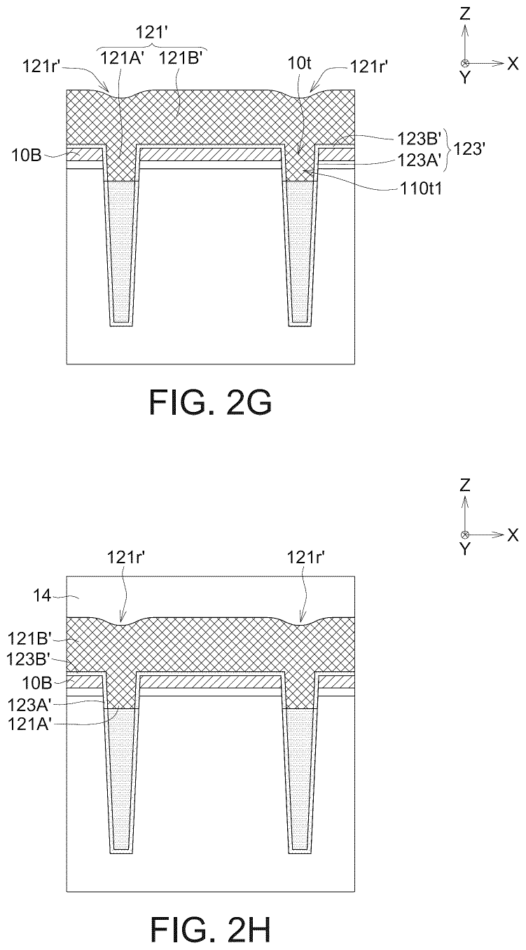

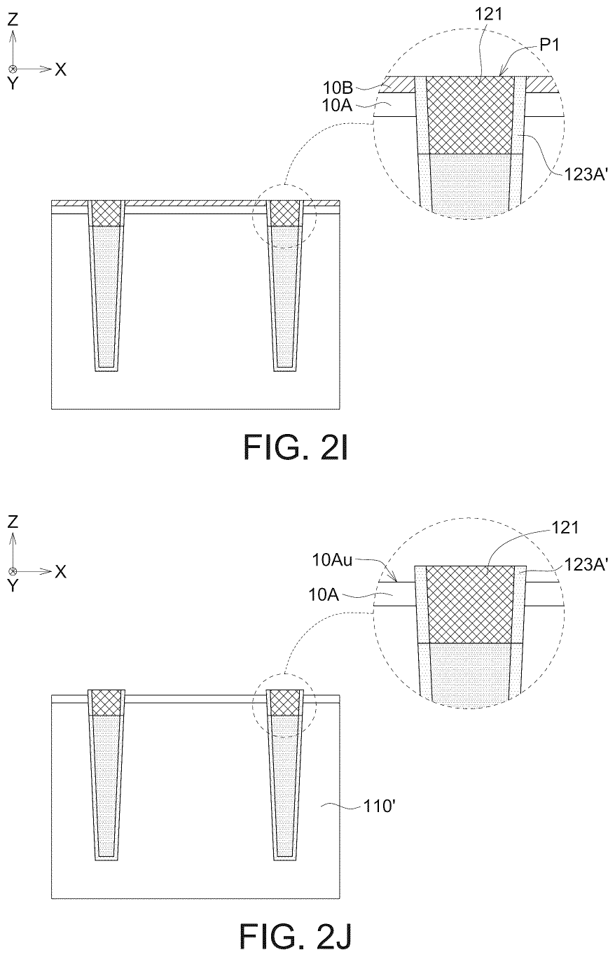

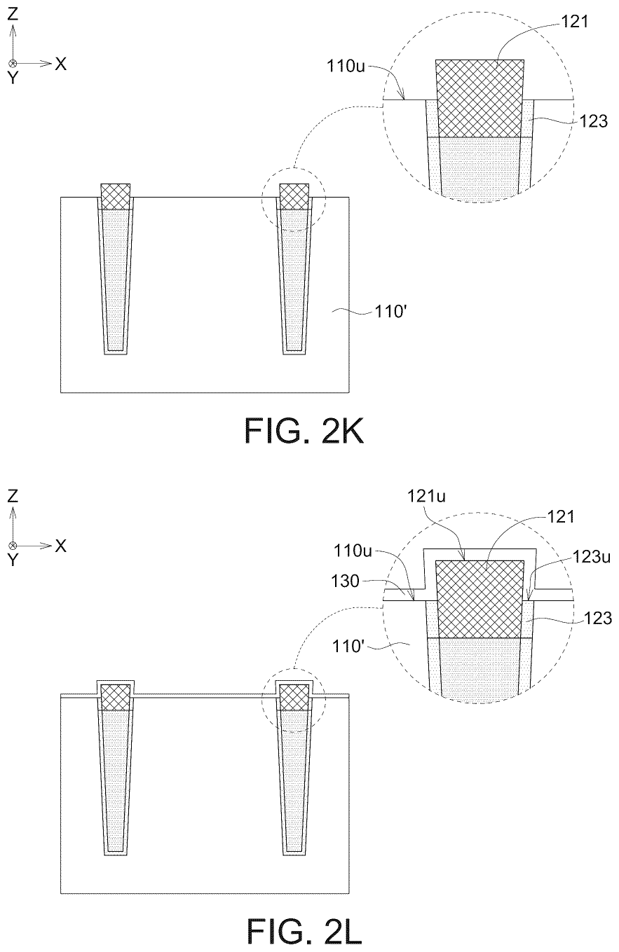

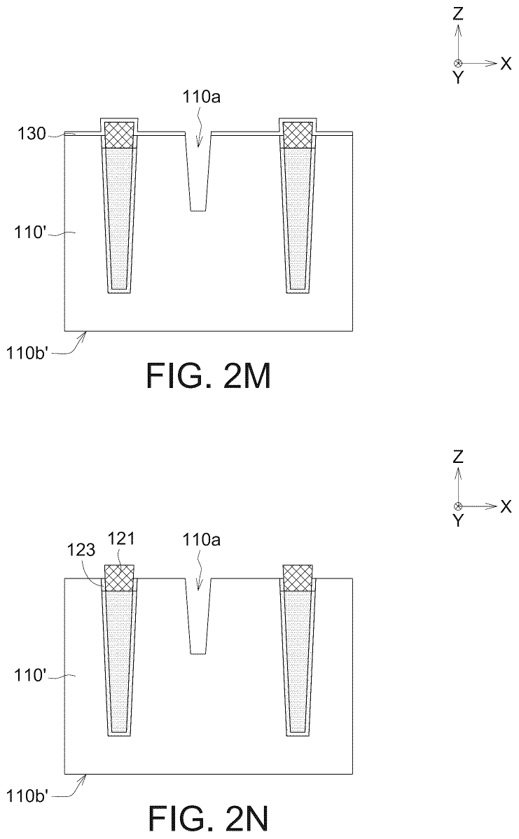

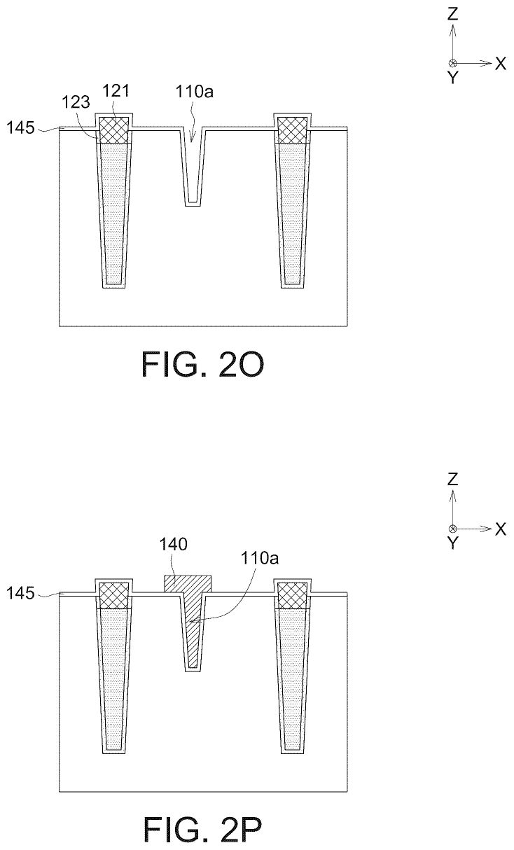

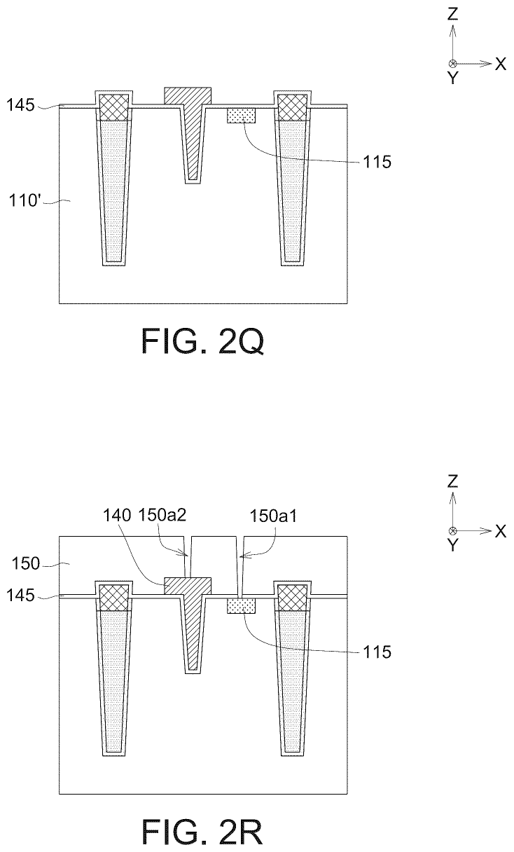

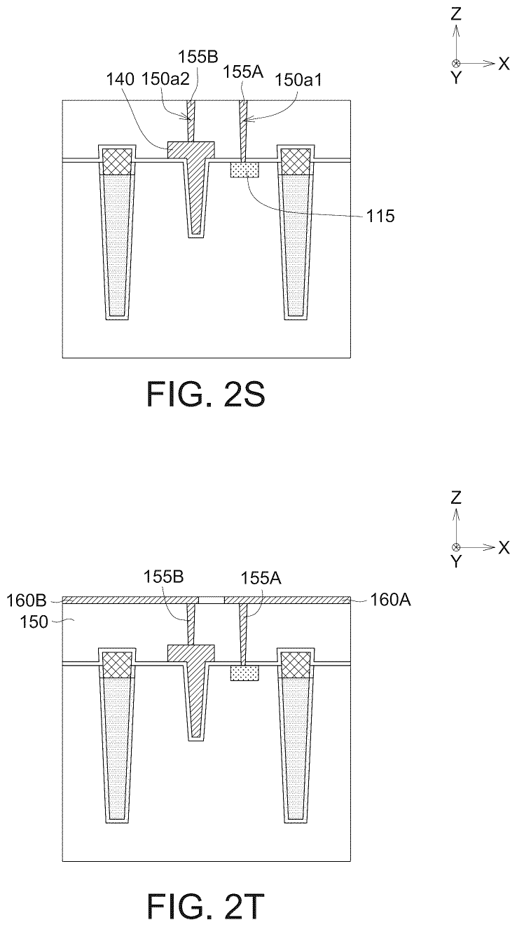

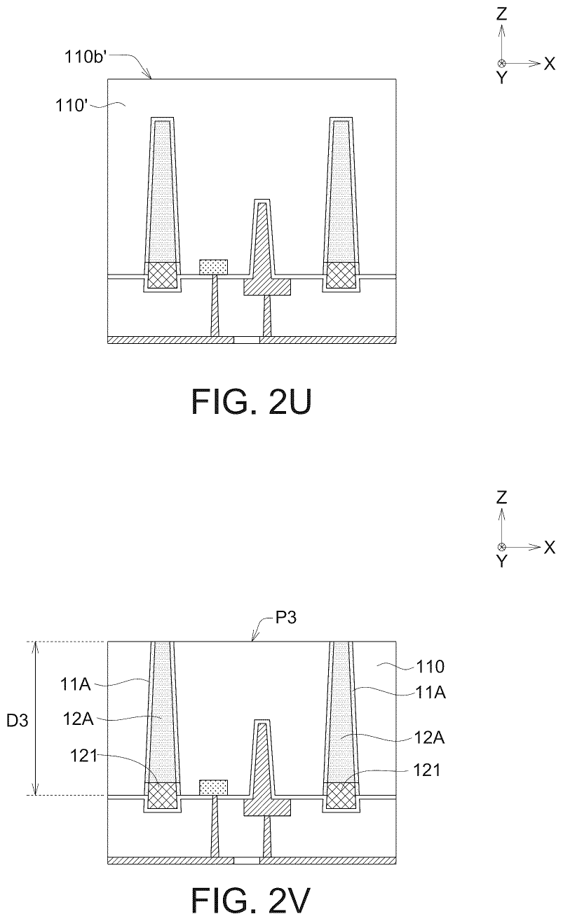

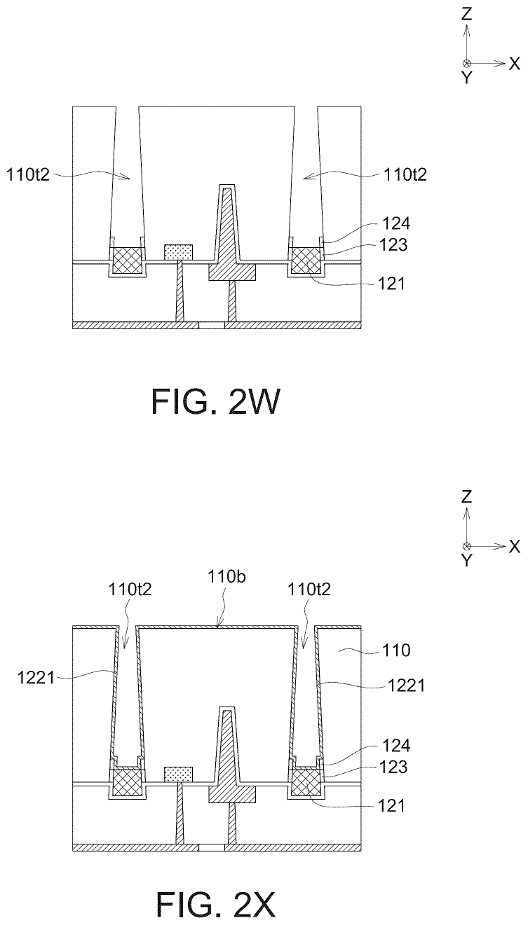

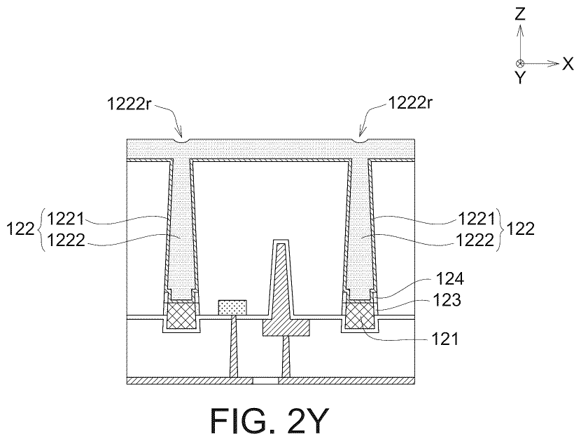

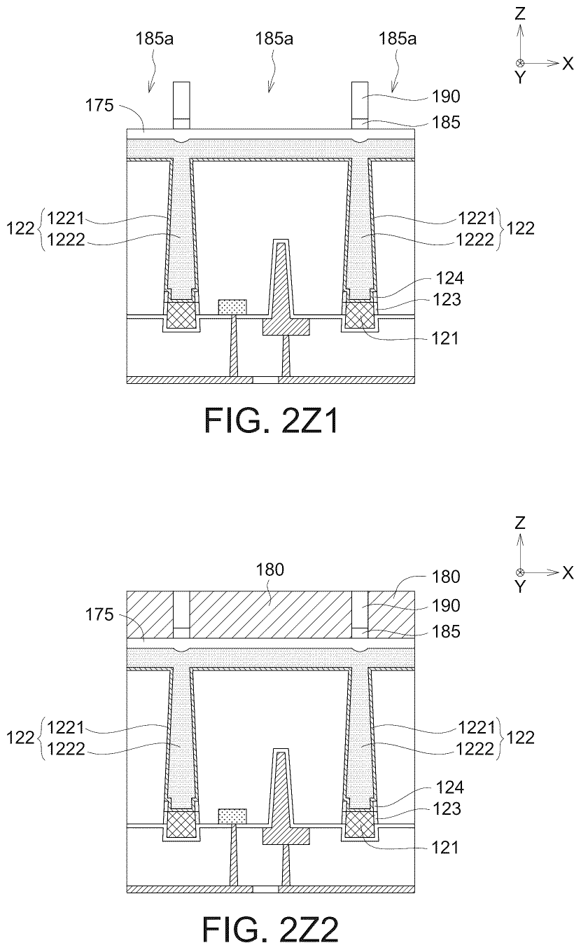

FIGS. 2A to 2Z2 illustrate schematic diagrams of manufacturing processes of the photo-sensing device 100 of FIG. 1. FIGS. 2A to 2T illustrate the front-side process, while processes of FIGS. 2U to 2Z2 illustrate the back-side process. In the front-side process, the first surface 110u faces upward for processing, and in the back-side process, the second surface 110b faces upward for processing.

As illustrated in FIG. 2A, an oxide layer 10A, a hard mask 10B, a BARC (Bottom Anti-Reflection Coating) layer 10C and a photoresist 10D are formed on the substrate 110′ in order by using, for example, deposition. The photoresist 10D may be patterned by using, for example, exposure, development and/or etching. The photoresist 10D has at least one opening 10D1 for defining at least one region of the trench 110t (as illustrated in FIG. 2B). The substrate 110′ is, for example, a silicon wafer. The substrate 110′ has a thickness T1, wherein the thickness T1 is, for example, 775 micrometers (μm). In addition, the hard mask 10B may be formed of, for example, nitride, and the BARC layer 10C may be formed of, for example, organic oxides.

As illustrated in FIG. 2B, at least one trench 110t and at least one trench 10t are formed through the opening 10D1 of the photoresist 10D by using, for example, dry etching. The trench 110t passes through the BARC layer 10C, the hard mask 10B and the oxide layer 10A, and the trench 110t is connected with the trench 10t and extends toward a second surface 110b′ of the substrate 110′ from the trench 10t. In addition, during etching, the entirety of the photoresist 10D may be removed and the BARC layer 10C may be thinned. The trench 110t has a first depth D1 in a direction Z and a first width W1 in a direction X, wherein the trench 110t has a first aspect ratio of the first depth D1 to the first width W1. In an embodiment, the first aspect ratio may be equal to or greater than 27. In an embodiment, the first depth D1 may range between 2 μm and 5 μm, greater or less. In the present embodiment, the trench 110t is formed in the front-side process, and thus no back-side dry etch to cause Si damage.

As illustrated in FIG. 2C, the BARC layer 10C in FIG. 2B may be removed by using, for example, wet etching (or wet cleaning). The wet etching does not over-damage the layer including silicon. Furthermore, the wet etching just causes little damage to the sidewall of the trench 110t.

As illustrated in FIG. 2D, a liner layer 11 may be formed on the sidewall of the trench 110t, a sidewall of the trench 10t and an upper surface of the hard mask 10B by oxidization technique. The liner layer 11 may be formed of oxide, for example, silicon oxide. The liner layer 11 has a delicate and uniform structure and it may help subsequent structures (for example, the sacrificial layer 12 in FIG. 2E) tightly and securely formed in the trench. The liner layer 11 includes a first portion 11A and a second portion 11B, wherein the first portion 11A is formed within the sidewall of the trench 110t and the sidewall of the trench 10t, and the second portion 12A is formed over the upper surface of the hard mask 10B.

Then, the structure in FIG. 2D may be heated at a temperature higher than 1000° C. by using, for example, annealing technique. The annealing may improve or recover the crystal lattice defect of the sidewall of the trench 110t resulted from the etching to the trench 110t in FIG. 2C. The annealing is applied to the structure in FIG. 2D in the front-side process. In the front-side process, the metal material (for example, the gate via, the gate 140, the contact vias 155A and 155B and the conductive traces 160A and 160B) has not formed yet, and thus the annealing does not damage such metal material.

As illustrated in FIG. 2E, a sacrificial layer 12 may be formed on the liner layer 11 by using deposition, for example, CVD (chemical vapor deposition). The sacrificial layer 12 includes a first portion 12A and a second portion 12B, wherein the first portion 12A is formed on the first portion 11A, and the second portion 12B is formed on the second portion 11B. In addition, the sacrificial layer 12 is formed of, for example, oxide.

As illustrated in FIG. 2F, the second portion 11B of the liner layer 11, a portion of the first portion 11A of the liner layer 11, the second portion 12B of the sacrificial layer 12, a portion of the first portion 12A of the sacrificial layer 12 and a portion of the hard mask 10B may be removed by using, for example, etching back. After etching, the trench 10t and a first portion 110t1 of the trench 110t are exposed. The first portion 110t1 has a second depth D2 and a second width W2, wherein the first portion 110t1 has a second aspect ratio of the second depth D2 to the second width W2. In an embodiment, the second aspect ratio may be equal to or less than 0.6. In an embodiment, the second depth D2 may range between, for example, 60 nanometers (nm) and 70 nm, 70 nm and 80 nm, greater or less. In an embodiment, for the same the etchant, the hard mask 10B has an etching rate lower than that of the liner layer 11 and the sacrificial layer 12. As a result, the removed material of the liner layer 11 and the sacrificial layer 12 is more than that of the hard mask 10B. When the first portion 110t1 is formed, the hard mask 10B is still remained but thinned.

As illustrated in FIG. 2G, a first oxide material 123′ is formed by using that process the same as or similar to that of the liner layer 11. The first oxide material 123′ includes a first portion 123A′ and a second portion 123B′, wherein the first portion 123A′ is formed on the sidewall of the trench 10t and a sidewall of the first portion 110t1, and the second portion 123B′ is formed over the upper surface of the hard mask 10B. Then, an etching stop layer material 121′ over the first oxide material 123′ is formed by using, for example, CVD. The etching stop layer material 121′ includes a first portion 121A′ and a second portion 121B′, wherein the first portion 121A′ is formed within the trench 10t and the first portion 110t1, and the second portion 121B′ is formed over the second portion 123B′ of the first oxide material 123′. Due to the trench 10t, the second portion 121B′ may form the depression 121r′ corresponding to the trench 10t.

As illustrated in FIG. 2H, a BARC layer 14 over the etching stop layer material 121′ is formed by using coating (for example, spin coating), applying, etc. The BARC layer 14 may fills at least one depression 121r′ of the etching stop layer material 121′ for obtaining a planarized (or flat) surface by a CMP (Chemical-Mechanical Planarization) in FIG. 2I.

As illustrated in FIG. 2I, the BARC layer 14, the second portion 121B′ of the etching stop layer material 121′, a portion of the first portion 121A′ of the etching stop layer material 121′, the second portion 123B′ of the first oxide material 123′, a portion of the first portion 123A′ of the first oxide material 123′ and a portion of the hard mask 10B may be removed by using, for example, CMP. After CMP, the hard mask 10B is thinned a remained portion of the first portion 121A′ forms the etching stop layer 121. In addition, After CMP, the hard mask 10B, the first oxide layer 123 and etching stop layer 121 may form a planarized surface (or coplanar) P1.

As illustrated in FIG. 2J, the hard mask 10B in FIG. 2I is removed to expose the oxide layer 10A by using, for example, wet etching (or wet cleaning). After etching, the etching stop layer 121 and the first portion 123A′ of the first oxide material 123′ may protrude relative to an upper surface 10Au of the oxide layer 10A.

As illustrated in FIG. 2K, the oxide layer 10A and a portion of the first portion 123A′ in FIG. 2J may be removed to expose the substrate 110′ by using, for example, wet etching. A remaining portion of the first portion 123A′ in FIG. 2J forms the first oxide layer 123. In addition, the first oxide layer 123 may be protruded or recessed relative to the first surface 110u of the substrate 110′.

As illustrated in FIG. 2L, the insulation layer (or sacrificial layer) 130 over the first surface 110u of the substrate 110′, the etching stop layer 121 and the first oxide layer 123 is formed by using, for example, deposition, etc., The insulation layer 130 is formed on the first surface 110u of the substrate 110, the first surface 121u of the etching stop layer 121, the lateral surface of the etching stop layer 121 and the first surface 123u of the first oxide layer 123.

Then, although not illustrated, at least one N-type region and at least one P-type region may be implanted in the substrate 110′.

As illustrated in FIG. 2M, after implanted, at least one hole 110a extending toward the second surface 110b′ from an upper surface of the insulation layer 130 is formed by using, for example, deposition, photolithography, etching, etc.

As illustrated in FIG. 2N, the insulation layer 130 in FIG. 2M is removed to expose the etching stop layer 121 and the first oxide layer 123 by using, for example, etching back.

As illustrated in FIG. 2O, the gate dielectric layer 145 over a sidewall of the hole 110a, the etching stop layer 121 and the first oxide layer 123 is formed by using, for example, deposition, etc.

As illustrated in FIG. 2P, at least one gate 140 within the hole 110a and on the gate dielectric layer 145 is formed by using, for example, deposition, photolithography, etching, plating, etc. The gate dielectric layer 145 may isolate the substrate 110′ from the gate 140.

As illustrated in FIG. 2Q, at least one doping region 115 may be formed within the substrate 110′ by using implanting. The doping region 115 is, for example, N-type doping region.

As illustrated in FIG. 2R, the dielectric layer 150 over the gate dielectric layer 145 and the gate 140 is formed by using, for example, deposition. At least one opening 150al and at least one opening 150a2 may be formed in the dielectric layer 150 by using, for example, deposition, photolithography, etching, etc. The opening 150al extends to the doping region 115 through the dielectric layer 150 and the gate dielectric layer 145, and the opening 150a2 extends to the gate 140 through the dielectric layer 150.

As illustrated in FIG. 2S, the contact via 155A filling the opening 150al and the contact via 155B filling the opening 150a2 are formed by using, for example, deposition, photolithography, etching, etc. The contact via 155A is electrically connected with the doping region 115, and the contact via 155B is electrically connected with the gate 140.

As illustrated in FIG. 2T, at least one conductive trace 160A and at least one conductive trace 160B disposed on the dielectric layer 150 are formed by using, for example, deposition, photolithography, etching, etc. The conductive trace 160A is electrically connected with the contact via 155A, and the conductive trace 160B is electrically connected with the contact via 155B.

Then, although not illustrated, the structure in FIG. 2T may be connected with another wafer on which at least one circuit is formed, wherein the conductive traces 160A of the structure in FIG. 2T is connected with the another wafer.

As illustrated in FIG. 2U, the structure in FIG. 2T is inverted to make the second surface 110b′ face upward.

As illustrated in FIG. 2V, a portion of the substrate 110′, a portion of the first portion 11A (selectively) and a portion of the first portion 12A (selectively) in FIG. 2U may be removed by, for example, CMP, etching back, etc. After removed, the substrate 110′ in FIG. 2V is thinned to form the substrate 110, and the substrate 110, the first portion 11A and the first portion 12A form a planarized surface (or coplanar) P3. The substrate 110 has a depth D3 ranging between, for example, 2 μm and 3 μm, 3 μm and 5 μm, greater or less.

As illustrated in FIG. 2W, a portion of the first portion 11A of the liner layer 11 and the first portion 12A in FIG. 2V are removed to expose a second portion 110t2 of the trench 110t by using, for example, wet etching (or wet cleaning). In addition, the wet etching does not over-damage the layer including silicon. Furthermore, the wet etching just causes little damage to the sidewall of the trench 110t. After etching, a remained portion of the first portion 11A forms the second oxide layer 124. In another embodiment, the entirety of the first portion 11A in FIG. 2V may be removed.

As illustrated in FIG. 2X, the high-k portion 1221 covering the second surface 110b of the substrate 110, the sidewall of the second portion 110t2 of the trench 110t, the second oxide layer 124 and the etching stop layer 121 is formed by using, for example, deposition. The high-k portion 1221 conforms with the shapes of the second surface 110b of the substrate 110, the sidewall of the second portion 110t2 of the trench 110t, the second oxide layer 124 and the etching stop layer 121.

As illustrated in FIG. 2Y, the oxide portion 1222 covering the high-k portion 1221 is formed by using, for example, deposition. The oxide portion 1222 and the high-k portion 1221 construct the solation layer 122. Due to the second portion 110t, the oxide portion 1222 may form the depression 1222r corresponding to the second portion 110t2.

As illustrated in FIG. 2Z1, the layer 175 is formed over the oxide portion 1222 of the trench isolation 120. The layer 175 may, for example, be or includes an oxide, such as silicon dioxide, or the like. In some embodiments, the layer 175 is formed by a PVD process, a CVD process, an ALD process, or some other suitable growth or deposition process. In another embodiment, the layer 175 may be ARC (Anti-reflective coating).

Then, a plurality of the conductive grid structure 185 is formed over the layer 175 and a plurality of the dielectric grid structure 190 is formed over the conductive grid structures 185. In some embodiments, a process for forming the conductive grid structure 185 and the dielectric grid structure 190 includes: depositing (e.g., by PVD, CVD, ALD, electroplating, electroless plating, etc.) a metal grid layer over the layer 175; depositing (e.g., by PVD, CVD, ALD, etc.) the dielectric grid layer on the metal grid layer; forming a masking layer (not shown) over the dielectric grid layer; patterning the metal grid layer and the dielectric grid layer according to the masking layer; and performing a removal process to remove the masking layer. The conductive grid structure 185 and the dielectric grid structure 190 include sidewalls that define a plurality of openings 185a each overlying the corresponding pixel region PA.

As illustrated in FIG. 2Z2, the light filters 180 are formed over or corresponding to the pixel regions PA. In some embodiments, the light filters 180 may be deposited by, for example, CVD, PVD, ALD, or some other suitable deposition or growth process. The light filters 180 are disposed in the openings 185a (the openings 185a is illustrated in FIG. 2Z1) defined by the sidewalls of the conductive grid structure 185 and the dielectric grid structure 190.

Then, the micro-lenses 195 in FIG. 1 are formed over the light filters 180 in FIG. 2Z2, wherein each micro-lens 195 overlies the corresponding light filter 180 and is configured to focus the incident light towards the pixel regions PA. In some embodiments, the micro-lenses 195 may be deposited by, for example, CVD, PVD, ALD, or some other suitable deposition or growth process.

Although not illustrated, the structure in FIG. 2Z2 may be singulated by using, for example, sawing to form one photo-sensing device 100 or a plurality of the photo-sensing devices 100 in FIG. 1.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a photo-sensing device includes a substrate and a trench isolation. A trench is formed in the substrate for the filling of the trench isolation. The trench is formed in the front-side process, and it may obtain at least one of the following advantages: more Si active area for electric full well capacity enhancement; less Si damage by more thermal recovery; and more high-k passivation area for better electric performance.

Example embodiment 1: a photo-sensing device includes a substrate and a trench isolation. The substrate has a pixel region. The trench isolation is disposed within the substrate, defines the pixel region and incudes an etching stop layer and an isolation structure. The isolation structure is connected with the etching stop layer. The etching stop layer has a minimum width in a direction, the isolation portion has a maximum width in the direction, and the minimum width and the maximum width are different.

Example embodiment 2 based on Example embodiment 1: the substrate has a trench, at least one portion of the trench isolation is disposed within the trench, and the trench isolation further includes a first oxide layer disposed on a sidewall of the trench. The etching stop layer covers the first oxide layer.

Example embodiment 3 based on Example embodiment 2: the etching stop layer has a surface, and the trench isolation further includes a second oxide layer. The second oxide layer is disposed on a sidewall of the trench, connected with the first oxide layer and protrudes relative to the surface of the etching stop layer.

Example embodiment 4 based on Example embodiment 2: the substrate further has a first surface and a second surface opposite to the first surface, the trench extends to the second surface from the first surface, and the first oxide layer is protruded or recessed relative to the first surface.

Example embodiment 5 based on Example embodiment 1: the substrate has a trench, and the isolation structure includes a high-k portion and an oxide portion. The high-k portion is disposed on a sidewall of the trench. The oxide portion covers the high-k portion.

Example embodiment 6 based on Example embodiment 3: the isolation structure includes a high-k portion. The high-k portion is disposed on a sidewall of the trench and covers an end of the second oxide layer and the surface of the etching stop layer.

Example embodiment 7 based on Example embodiment 1: the etching stop layer is formed of poly silicon.

Example embodiment 8: a photo-sensing device includes a substrate and a trench isolation. The substrate has a pixel region, a trench, a first surface and a second surface opposite to the first surface. The trench isolation is at least partially disposed within the trench of the substrate, and defines the pixel region. The trench extends to the second surface from the first surface, and has an inner width decreasing from the first surface toward the second surface.

Example embodiment 9 based on Example embodiment 8: the trench isolation includes an etching stop layer and an isolation structure connecting the etching stop layer. The etching stop layer has a minimum width in a direction, the isolation portion has a maximum width in the direction, and the minimum width and the maximum width are different.

Example embodiment 10 based on Example embodiment 9: the trench isolation further includes a first oxide layer disposed on a sidewall of the trench. The etching stop layer covers the first oxide layer.

Example embodiment 11 based on Example embodiment 10: the etching stop layer has a surface, the trench isolation further includes second oxide layer. The second oxide layer is disposed on a sidewall of the trench, connected with the first oxide layer and protrudes relative to the surface of the etching stop layer.

Example embodiment 12 based on Example embodiment 10: the trench extends to the second surface from the first surface, and the first oxide layer is protruded or recessed relative to the first surface.

Example embodiment 13 based on Example embodiment 9: the isolation structure includes a high-k portion and an oxide portion. The high-k portion is disposed on a sidewall of the trench. The oxide portion covers the high-k portion.

Example embodiment 14 based on Example embodiment 11: the isolation structure includes a high-k portion. The high-k portion is disposed on a sidewall of the trench and covers an end of the second oxide layer and the surface of the etching stop layer.

Example embodiment 15 based on Example embodiment 9: the etching stop layer is formed of poly silicon.

Example embodiment 16: a manufacturing method for a photo-sensing device includes the following steps: forming a trench in a substrate, wherein the substrate has a first surface and a second surface opposite to the first surface, and the trench extends toward the second surface from the first surface, the trench has an inner width decreasing from the first surface toward the second surface; forming an etching stop layer within the trench; and forming an isolation structure within the trench and connecting the etching stop layer.

Example embodiment 17 based on Example embodiment 16: in forming the trench in the substrate, the first surface faces upward, and after forming the trench in the substrate, the manufacturing method further includes: annealing a sidewall of the trench.

Example embodiment 18 based on Example embodiment 16: the manufacturing method further includes: inverting the substrate to make the second surface face upward; and after inverting the substrate, forming a gate in the substrate.

Example embodiment 19 based on Example embodiment 16: the manufacturing method further includes: forming a liner layer on a sidewall of the trench; forming a sacrificial layer on the liner; removing a portion of the liner layer and a portion of the sacrificial layer to expose a first portion of the trench; and forming the etching stop layer within a first portion of the trench.

Example embodiment 20 based on Example embodiment 19: the manufacturing method further includes: removing another portion of the liner layer and another portion of the sacrificial layer to expose a second portion of the trench; and forming the solation layer within the second portion of the trench.

Example embodiment 21 based on Example embodiment 1: the minimum width is less than the maximum width.

Example embodiment 22 based on Example embodiment 9: the minimum width is less than the maximum width.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photo-sensing device, comprising:
a substrate having a pixel region; and
a trench isolation disposed within the substrate, defining the pixel region and comprising:
an etching stop layer; and
an isolation structure connecting the etching stop layer;
wherein the etching stop layer has a minimum width in a direction, the isolation portion has a maximum width in the direction, and the minimum width and the maximum width are different.

2. The photo-sensing device as claimed in claim 1, wherein the substrate has a trench, at least one portion of the trench isolation is disposed within the trench, and the trench isolation further comprises:
a first oxide layer disposed on a sidewall of the trench;
wherein the etching stop layer covers the first oxide layer.

3. The photo-sensing device as claimed in claim 2, wherein the etching stop layer has a surface, the trench isolation further comprises:
a second oxide layer disposed on a sidewall of the trench, connected with the first oxide layer and protruding relative to the surface of the etching stop layer.

4. The photo-sensing device as claimed in claim 2, wherein the substrate further has a first surface and a second surface opposite to the first surface, the trench extends to the second surface from the first surface, and the first oxide layer is protruded or recessed relative to the first surface.

5. The photo-sensing device as claimed in claim 1, wherein the substrate has a trench, and the isolation structure comprises:
a high dielectric constant (high-k) portion disposed on a sidewall of the trench; and
an oxide portion covering the high-k portion.

6. The photo-sensing device as claimed in claim 3, wherein the isolation structure comprises:
a high-k portion disposed on a sidewall of the trench and covering an end of the second oxide layer and the surface of the etching stop layer.

7. The photo-sensing device as claimed in claim 1, wherein the etching stop layer is formed of poly silicon.

8. A photo-sensing device, comprising:
a substrate having a pixel region, a trench, a first surface and a second surface opposite to the first surface; and
a trench isolation at least partially disposed within the trench of the substrate, and defining the pixel region;
wherein the trench extends to the second surface from the first surface, and has an inner width decreasing from the first surface toward the second surface.

9. The photo-sensing device as claimed in claim 8, wherein the trench isolation comprises:
an etching stop layer; and
an isolation structure connecting the etching stop layer;
wherein the etching stop layer has a minimum width in a direction, the isolation portion has a maximum width in the direction, and the minimum width is less than the maximum width.

10. The photo-sensing device as claimed in claim 9, wherein the trench isolation further comprises:
a first oxide layer disposed on a sidewall of the trench;
wherein the etching stop layer covers the first oxide layer.

11. The photo-sensing device as claimed in claim 10, wherein the etching stop layer has a surface, the trench isolation further comprises:
a second oxide layer disposed on a sidewall of the trench, connected with the first oxide layer and protruding relative to the surface of the etching stop layer.

12. The photo-sensing device as claimed in claim 10, wherein the trench extends to the second surface from the first surface, and the first oxide layer is protruded or recessed relative to the first surface.

13. The photo-sensing device as claimed in claim 9, wherein the isolation structure comprises:
a high-k portion disposed on a sidewall of the trench; and
an oxide portion covering the high-k portion.

14. The photo-sensing device as claimed in claim 11, wherein the isolation structure comprises:
a high-k portion disposed on a sidewall of the trench and covering an end of the second oxide layer and the surface of the etching stop layer.

15. The photo-sensing device as claimed in claim 9, wherein the etching stop layer is formed of poly silicon.

16. A manufacturing method for a photo-sensing device, comprising:
forming a trench in a substrate, wherein the substrate has a first surface and a second surface opposite to the first surface, and the trench extends toward the second surface from the first surface, the trench has an inner width decreasing from the first surface toward the second surface;
forming an etching stop layer within the trench; and
forming an isolation structure within the trench and connecting the etching stop layer.

17. The manufacturing method as claimed in claim 16, wherein in forming the trench in the substrate, the first surface faces upward, and after forming the trench in the substrate, the manufacturing method further comprises:
annealing a sidewall of the trench.

18. The manufacturing method as claimed in claim 16, further comprising:
inverting the substrate to make the second surface face upward; and
after inverting the substrate, forming a gate in the substrate.

19. The manufacturing method as claimed in claim 16, further comprising:
forming a liner layer on a sidewall of the trench;
forming a sacrificial layer on the liner layer;
removing a portion of the liner layer and a portion of the sacrificial layer to expose a first portion of the trench; and
forming the etching stop layer within a first portion of the trench.

20. The manufacturing method as claimed in claim 19, further comprising:
removing another portion of the liner layer and another portion of the sacrificial layer to expose a second portion of the trench; and
forming the solation layer within the second portion of the trench.
